(19) United States
(12) Patent Application Publication
(10) Pub. No.: US 2003/0194846 A1
(43) Pub. Date: Oct. 16, 2003

(54) Medium dose simox over a wide BOX thickness range by a multiple implant, multiple anneal process

(75) Inventors: Harold J. Hovel, Katonah, NY (US); Maurice H. Norcott, San Jose, CA (US); Devendra K. Sadana, Pleasantville, NY (US)

Correspondence Address: Steven Fischman, SCULLY, SCOTT, MURPHY & PRESSER, 400 Garden City Plaza, Garden City, NY, 11530, US

(73) Assignee: International Business Machines Corp., Armonk, NY

(21) Appl. No.: 10/122,009

(22) Filed: Apr. 11, 2002

(51) Int. Cl. H01L 21/76

(52) U.S. Cl. 438/400

(57) ABSTRACT

A method of fabricating a high-quality silicon-on-insulator (SOI) substrate material having a buried oxide (BOX) region that has a thickness of about 300 nm or less is provided. The method employs multiple implant, multiple annealing steps to form the high-quality SOI substrate. In particular the inventive method includes at least a first oxygen ion implant where a primary oxide seed region is formed, a first annealing step, a second oxygen ion implant where a BOX-adjusting oxide seed region is formed and a second annealing step. The annealing steps convert the seed regions into buried oxide regions.

### CROSS REFERENCE TO RELATED APPLICATIONS

This application is cross-referenced to co-assigned U.S. application Ser. No. 09/861,593, filed May 21, 2001 (YOR9199970117US3), which is a continuation-in-part application of U.S. Pat. No. 6,259,137, which issued Jul. 10, 2001, which is a divisional application of U.S. Pat. No. 5,930,643, which issued Jul. 27, 1999; co-assigned U.S. application Ser. No. 09/356,195, filed July 1999 (YOR919990101US1); co-assigned U.S. application Ser. No. 09/861,596, filed May 21, 2001 (YOR920010102US1); co-assigned U.S. application Ser. No. 09/861,594, filed May 21, 2001 (YOR920010103US1); co-assigned U.S. application Ser. No. 09/884,670, filed Jun. 19, 2001 (YOR920010104US1), the entire contents of each are incorporated herein by reference.

### DESCRIPTION

1. Field of the Invention

The present invention relates to silicon-on-insulator (SOI) substrates, and more particularly to a separation by implantation of oxygen (SIMOX) process in which a high-quality SOI substrate material is provided that has a buried oxide (BOX) thickness of about 300 nm or less.

2. Background of the Invention

High-speed, low-power integrated circuits (ICs) require small, sub-micron gate lengths. To take advantage of these advanced designs and device dimensions, it is advantageous to develop SOI (silicon-on-insulator) substrates with thin buried oxide (BOX) regions. SOI substrates can be either produced by a conventional bonding and thinning process or by SIMOX wherein oxygen ions are implanted into a Si-containing wafer and thereafter a high-temperature annealing step (on the order of about 1100° C. or above) is employed to convert the implanted oxygen ions into a BOX region. Fabricating SOI substrates using SIMOX provides a manufacturer more flexibility than a conventional bonding and thinning process.

The cost of SOI substrates using SIMOX is nearly proportional to the BOX thickness, and the number of wafers that can be produced by a single SIMOX implanter is inversely proportional to it. Therefore, SIMOX substrates, in which the present BOX thickness is between 360 to 400 nm, will be moving in the direction of even thinner BOX regions in the future.

At present, SIMOX manufactures produce a fraction of SIMOX substrates with thinner BOX regions using “low-dose” and “medium-dose” processes. A typical prior art low-dose process is carried out using an ion dose of about 4E17 cm⁻² or less, whereas a typical prior art medium-dose process is carried out using an ion dose of from about 6E17 to about 1.2E17 cm⁻².

Specifically, the main prior art technique to produce thinner BOX regions is to reduce the dose of implanted oxygen ions, since the thickness is proportional to this dose. By implanting about ¼ of the standard dose (i.e., 1.6-1.8E18 cm⁻²), or about 4E17 cm⁻², a BOX thickness of about 100 nm is produced. By implanting a second dose of about 2E17 or 4E17 cm⁻² after the first anneal, an SOI substrate having a BOX thickness of either 150 or 200 nm can be produced.

BOX regions formed by a single implant and single anneal process in the dose range of 1.2E17 to 1.6E17 cm⁻² are problematic in that the BOX regions, despite being continuous, can contain a large number of undesirable Si islands which cause severe electrical problems such as leakage. The presence of a large number of undesirable Si islands in the BOX region of an SOI substrate makes the SOI substrate unusable. For this reason, SIMOX with a single anneal is generally available with BOX thicknesses of approximately 100 nm (low-dose) and 360-400 nm (standard dose). SIMOX with a BOX thickness in the range from 150-200 nm (medium-dose) typically requires multiple implants and multiple anneals to produce high-quality BOX regions.

In view of the drawbacks mentioned hereinabove with prior art SIMOX processes, there is a continued need to develop a new and improved SIMOX process which is capable of fabricating an SOI substrate that comprises a buried oxide region that is continuous, has a thickness of about 300 nm or less, and has a fewer number of Si islands which reduces the potential leakage problems present in prior art SOI substrates.

### SUMMARY OF THE INVENTION

One object of the present invention is to provide a method of fabricating a high-quality SOI substrate material.

Another object of the present invention is to provide a method of fabricating a high-quality SOI substrate material that has a continuous and tailor made BOX region.

A further object of the present invention is to provide a method of fabricating a high-quality SOI substrate material that has a continuous BOX region whose thickness is about 300 nm or less, preferably from about 100 nm to about 250 nm.

A yet further object of the present invention is to provide a method of fabricating a high-quality SOI substrate material that comprises a BOX region that contains little or no Si islands therein.

A still further object of the present invention is to provide a method of fabricating a high-quality SOI substrate material using a SIMOX process.

An even further object of the present invention is to provide a method of fabricating a high-quality SOI substrate material which has little or no current leakage associated therewith.

These and other objects and advantages are achieved in the present invention by utilizing a method which includes multiple implanting and annealing steps. Specifically, the method of the present invention, which forms a high-quality buried oxide region having a thickness of about 300 nm or less within a Si-containing substrate, comprises the steps of:

forming a primary oxide seed region into a Si-containing substrate;

subjecting said Si-containing substrate containing said primary oxide seed region to a first annealing step to convert the primary oxide seed region into a first buried oxide region;

forming a BOX-adjusting oxide seed region into said Si-containing substrate proximate to said first buried oxide region; and

subjecting said Si-containing substrate to a second annealing step to convert said BOX-adjusting oxide seed region and said first buried oxide region into a second buried oxide region, said second buried oxide region is thicker, and of high quality, equal to or better than the first buried oxide region.

The primary and BOX-adjusting oxide seed regions may be formed using one or more oxygen ion implantation processes. Hence, each oxide seed region may comprise a single continuous or discontinuous oxide seed region or multiple continuous or discontinuous oxide seed regions. In one embodiment of the present invention, the primary oxide seed region and BOX-adjusting seed region are comprised of a base oxide seed region and a second oxide seed regions, respectively. The base oxide seed region of either the primary or BOX-adjusting oxide seed regions is formed by a base oxygen ion implantation process that is carried out at relatively high-temperatures, while the second oxide seed region of either seed regions is formed by a low-temperature, low-dose oxygen ion implantation process. In some embodiments, the low-temperature, low-dose oxygen ion implantation process is optional and need not be performed. In a highly preferred embodiment, the primary oxide seed region, which may be continuous or discontinuous, includes both a base implant induced seed region described below, and a second damaged region formed by a low-temperature, low-dose oxygen ion implantation process. The structure of the primary seed region without the low-temperature, low-dose oxygen ion implantation consists of damaged clusters intermixed with oxide precipitates with their depth distribution peaking at the projected range of the oxygen ion. The near-surface region may be substantially free of damaged clusters and oxide precipitates when the substrate temperature is greater than 200° C. The structure of the primary seed region with the low-temperature, low-dose oxygen ion implantation process consists of either an amorphous silicon which either overlaps with, or is separate from the damaged structure described above.

In the present invention, the first and second annealing steps recited above are each performed in an oxidizing ambient (about 0.1 to about 100%) that is admixed with an inert gas such as nitrogen or argon. The two annealing steps may use an identical or different oxidizing/inert gas admixture. Furthermore, the first and second annealing steps may be carried out using annealing temperatures and times which may range from about 1100° C. to about 1400° C. for a time period of from about 1 to about 50 hours. The annealing ambient may contain chlorine-containing gases or liquids. Chlorine may be used in all or some selected cycles of the anneal.

The term “Si-containing substrate” as used in the present invention denotes a semiconductor wafer that includes at least Si. Illustrative examples of such Si-containing substrates include, but are not limited to: Si, SiGe, SiC, SiCGe, nitrogen doped Si, epi-Si/Si and Si/SiGe.

It is emphasized that the SOI substrates fabricated using the inventive method comprise a BOX region having a thickness of about 300 nm or less which has a high-electrical quality associated therewith. The term “high-electrical quality” denotes that the SOI substrates of the present invention have a breakdown field of about 4 million volts/cm or more and a very low pinhole density of about <1 cm⁻² associated therewith. Moreover, the SOI substrates of the present invention have a continuous and uniform BOX region and they contain fewer Si islands as compared with prior art SOI substrates.

### BRIEF DESCRIPTION OF THE DRAWINGS

FIGS. 1A-1D are pictorial representations (through cross-sectional views) showing the basic processing steps that are employed in the method of the present invention.

FIGS. 2A-2B are pictorial representations (though cross-sectional views) showing an alternative embodiment of the present invention wherein an optional Si layer is employed.

FIGS. 3A-3I are pictorial representations (though cross-sectional views) showing some alternative embodiments of the present invention.

### DETAILED DESCRIPTION OF THE INVENTION

The present invention, which provides a method of fabricating an SOI substrate comprising a high-quality buried oxide region having a thickness tailored to be about 300 nm or less, preferably within the range from about 100 to about 250 nm, will now be described in greater detail by referring to the drawings that accompany the present application.

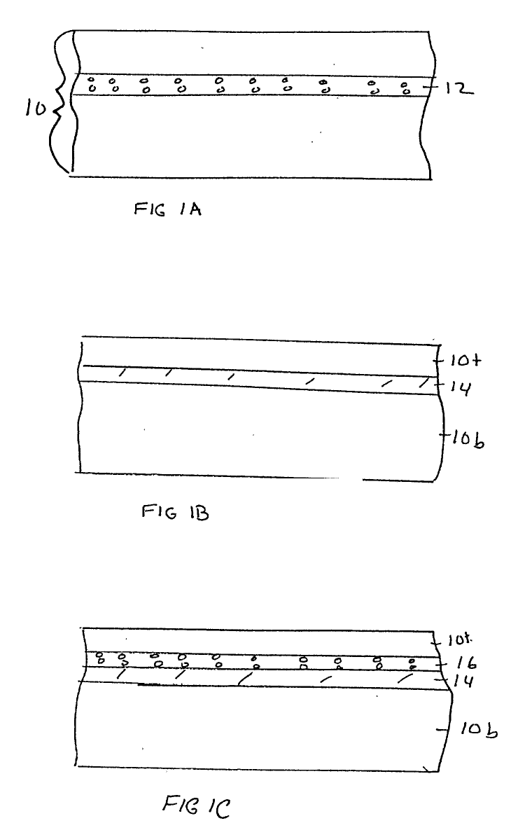

Reference is first made to FIGS. 1A-1D which are pictorial representations that illustrate the basic processing steps employed in the inventive method in fabricating an SOI substrate material that has a high-quality buried oxide region whose thickness is approximately 300 nm or less. More preferably, the inventive method forms a high-quality buried oxide region having a thickness that ranges from about 100 to about 250 nm.

In accordance with the inventive method, and as shown in FIG. 1A, primary oxide seed region 12 is formed into Si-containing substrate 10 by using at least one oxygen ion implantation step which is capable of forming the primary oxide seed region in the substrate. The primary seed region may be continuous or discontinuous.

As stated above, the term “Si-containing substrate” includes any Si-containing material such as Si, SiGe, SiC, SiCGe, nitrogen-doped Si, epi-Si/Si, and Si/SiGe. A preferred Si-containing substrate employed in the present invention is a Si wafer. The substrate may be undoped or doped (n- or p-type) depending on the future use of the SOI substrate material with or without an epitaxial Si layer.

The oxygen ion implant step employed in forming primary oxide seed region 12 may be a continuous ion implantation process, a pulse ion implantation process or a combination thereof. The primary oxide seed region may be continuous or discontinuous, (FIG. 1A shows the continuous version), or it may comprise multiple oxide seed regions that are formed using multiple oxygen ion implantation steps. The multiple oxide seed regions are not specifically shown, but are nevertheless meant to be included within primary oxide seed region 12. The structure of the primary seed region without the low-temperature, low-dose oxygen ion implantation consists of damaged clusters intermixed with oxide precipitates with their depth distribution peaking at the projected range of the oxygen ion. The near-surface region may be substantially free of damaged clusters and oxide precipitates when the substrate temperature is >200° C. The structure of the primary seed region with the low-temperature, low-dose oxygen ion implantation process consists of either an amorphous silicon which either overlaps with, or is separate from the damaged structure described above.

The single oxide seed region shown in FIG. 1A is also referred herein as a base oxide seed region which is formed using a base oxygen ion implantation process that is performed at a temperature of from about 200° to about 700° C. with an ion dose of from about 1E17 to about 8E17 cm⁻², with an ion dose of from about 2E17 to about 4E17 cm⁻² being more highly preferred. In addition to the above-mentioned ion doses, the base oxygen ion implant step is typically carried out in an ion implantation apparatus that operates at a beam current density of from about 0.05 to about 500 milliamps cm⁻² and at an energy of from about 120 to about 400 keV. More preferably, the base oxygen ion implant is performed at a beam current density from about 0.05 to about 50 milliamps cm⁻² and at an energy of from about 180 to about 240 keV.

In the embodiment wherein primary oxide seed region 12 is comprised of multiple oxide and damaged regions, primary oxide seed region 12 typically consists of damaged clusters intermixed with oxide precipitates with their depth distribution peaking at the projected range of the oxygen ion. The near-surface region may be substantially free of damaged clusters and oxide precipitates when the substrate temperature is >200° C. The structure of the primary seed region with the low-temperature, low-dose oxygen ion implantation process consists of either an amorphous silicon which either overlaps with, or is separate from the damaged structure described above. The low-temperature, low-dose oxygen ion implantation step may also be a continuous or pulse ion implantation process. In accordance with the present invention, the optional low-temperature, low-dose oxygen ion implant step is performed at a temperature of from about 4K to about 150° C. at an ion dose of from about 1E13 to about 5E15 cm⁻², with an ion dose of from about 5E14 to about 4E15 cm⁻² being more highly preferred.

In addition to the above-mentioned ion doses, the optional low-temperature, low-dose oxygen ion implant step is typically carried out in an ion apparatus that operates at a beam current density of from about 0.05 to about 500 milliamps cm⁻² and at an energy of from about 120 to about 400 keV. More preferably, the optional low-temperature, low-dose oxygen ion implant is performed at a beam current density from about 0.05 to about 50 milliamps cm⁻² and at an energy of from about 120 to about 240 keV.

The low-temperature, low-dose oxygen ion implant is carried out at, below, or near, room temperature. As defined above, room temperature denotes a temperature of from about 4K to about 150° C. More preferably, the low-temperature, low-dose oxygen ion implant is carried out at a temperature of from about −20° to about 100° C.

In one preferred embodiment of the present invention, the primary oxide seed region includes a base implant induced seed region and a region that is formed via the low-temperature, low-dose implant process mentioned above. It is noted that the various implant regions of the primary seed region are in proximity to each other.

The structure shown in FIG. 1A is then subjected to a first annealing step which is capable of converting primary oxide seed region 12 into first buried oxide region 14 (See, FIG. 1B). Specifically, the first annealing step is performed at a temperature of from about 1100° to about 1400° C. for a time period of from about 1 to about 50 hours. More preferably, the first annealing step is performed at a temperature of from about 1300° to about 1350° C. for a time period of from about 5 to about 20 hours.

The first annealing step of the present invention which converts primary oxide seed region 12 into first oxide region 14 is performed in an oxidizing ambient that is admixed with an inert gas. The term “oxidizing ambient” as used in the present invention denotes an ambient that includes at least one oxygen-containing gas therein. Illustrative examples of oxygen-containing gases that can be employed in the first annealing step include, but are not limited to: O₂, NO, N₂O, air, ozone or any combination thereof. The term “inert gas”, on the other hand, denotes a gas that includes Ar, N₂, He, Xe, Kr, Ne or any combination thereof. The annealing ambient may contain chlorine-containing gases or liquids. Chlorine may be used in all or some selected cycles of the anneal. When a chlorine-containing ambient is used, no inert gas is employed during the annealing process.

In accordance with the present invention, the first annealing may comprise an admixture comprising from about 0.1 to about 100% oxidizing ambient and from about 99.9 to about 0% inert gas. More specifically, the admixture employed in the first annealing step comprises from about 1 to about 50% oxidizing ambient and from about 99 to about 50% inert gas.

The first annealing step may be carried out by simply heating the Si-containing substrate containing the primary oxide seed region at a specific ramp temperature to the targeted temperature, or various ramp and soak cycles may be employed. During the various ramp and soak cycles, it is possible to vary the content of the annealing ambient. Also, it is possible to vary the annealing ambient during the various ramp and soak cycles of the first annealing step.

The resultant structure which is depicted in FIG. 1B comprises a top Si-containing layer 10t, first oxide region 14, and bottom Si-containing layer 10b. The thickness of the various layers may vary depending on the exact conditions employed in the oxygen ion implant steps as well as the first annealing step. Typically, however, the top Si-containing layer, at this point of the present invention, has a thickness of from about 100 to about 400 nm, with a thickness of from about 200 to about 400 nm being more highly preferred.

The thickness of the top Si layer can be further adjusted by growing an epitaxial Si layer (not shown in these drawings) over layer 10b. Insofar as the first oxide region is concerned, the oxide region formed at this point of the present invention has a thickness of about 300 nm or less, with a thickness of from about 100 to about 250 nm being more highly preferred. The thickness of the bottom Si-containing layer formed is inconsequential to the present invention.

Following the first annealing step, the structure shown in FIG. 1B is then subjected to at least one other oxygen implant step which forms BOX-adjusting oxide seed region 16 in the Si-containing substrate. As is the case with the primary seed region, the BOX-adjusting seed region may comprise a single oxide seed layer (as shown) or multiple oxide seed layers. The BOX-adjusting seed region is formed into a surface of Si-containing substrate 10 using a continuous or pulse ion implantation process. Combinations of these ion implantation processes are also contemplated herein.

In accordance with the present invention, the BOX-adjusting seed region may be formed using a base oxygen ion implant step that is preformed at an ion dose of from about 1E17 to about 8E17 cm⁻², with an ion dose of from about 2E17 to about 4E17 cm⁻² being more highly preferred. In addition to the above-mentioned ion doses, the base oxygen ion implant step used in forming the BOX-adjusting seed region is typically carried out in an ion implantation apparatus that operates at a beam current density of 0.05 to 500 mA cm⁻² and at an energy of from about 60 to about 240 keV. The implant employed in forming the BOX-adjusting oxide seed region is also carried out at a temperature of from about 200° to about 700°, with a temperature of from about 200° to about 600° C. being more highly preferred. The BOX-adjusting seed region is formed in proximity of first oxide region 14. Hence, the BOX-adjusting seed region may be formed above first buried oxide region 14 (as shown in FIG. 1C), below the first buried oxide region, or slightly or completely overlapping the first buried oxide region.

In cases wherein BOX-adjusting oxide seed region 16 is comprised of multiple seed layers, the multilayered BOX-adjusting oxide seed region may be formed by first utilizing the above mentioned base oxygen implant step followed by a second oxygen ion implantation step that is preformed at a lower temperature and lower dose than the base implant step. Typically, the low-temperature, low-dose oxygen ion implant used in forming the BOX-adjusting oxide seed region is performed at an ion dose of from about 1E13 to about 5E15 cm⁻², with an ion dose of from about 1E14 to about 4E15 cm⁻² being more highly preferred.

In addition to the above-mentioned ion doses, the low-temperature, low-dose oxygen implant using in forming the BOX-adjusting oxide seed region is typically carried out in an ion apparatus that operates at a beam current density of from about 0.05 to about 50 mA cm⁻² and at an energy of from about 20 to about 250 keV. More preferably, this ion implant is performed at a beam current density of from about 0.05 to about 5 mA cm⁻² and at an energy of from about 40 to about 210 keV. The low-temperature, low-dose oxygen implantation step used in forming the BOX-adjusting oxide seed region is carried out at a temperature of from about 4K to about 150° C., with a temperature of from about −20° to about 100° C. being more highly preferred.

In accordance with one aspect of the present invention, the total combined doses from all the oxygen implant steps employed in the present invention is between 5E17 to 1.2E8 cm⁻², with a combined dosage between 6E17 to 8E17 cm⁻² being more highly preferred.

Following the formation of the BOX-adjusting oxide seed region, the structure shown in FIG. 1C is then subjected to a second annealing step which is capable of converting BOX-adjusting oxide seed region 16 and first oxide region 14 into continuous and uniform second buried oxide region 18. Specifically, the second annealing step, which may be performed using the same or different oxidizing ambients and conditions as the first annealing step, is performed at a temperature of from about 1100° to about 1400° C. for a time period of from about 1 to about 50 hours. More preferably, the second annealing step is performed at a temperature of from about 1300° to about 1350° C. for a time period of from about 5 to about 20 hours.

The second annealing step of the present invention is performed in an oxidizing ambient that is also admixed with an inert gas. The terms “oxidizing ambient” and “inert gas” have the above-identified meaning. In accordance with the present invention, the second annealing step is carried out in an ambient that comprises an admixture comprising from about 0.1 to about 100% oxidizing ambient and from about 0.1 to about 99.9% inert gas. More specifically, the admixture employed in the second annealing step comprises from about 1 to about 50% oxidizing ambient and from about 99 to about 50% inert gas. The annealing ambient may contain chlorine-containing gases or liquids. Chlorine may be used in all or some selected cycles of the anneal.

The second annealing step may be carried out by simply heating the Si-containing substrate containing first oxide region 14 and BOX-adjusting oxide seed region 16 at a specific ramp temperature to the targeted temperature, or various ramp and soak cycles may be employed. During the various ramp and soak cycles, it is possible to vary the content of the annealing ambient. Also, it is possible to vary the annealing ambient during the various ramp and soak cycles of the first annealing step.

The resultant structure which is depicted in FIG. 1D comprises a top Si-containing layer 10t, second buried oxide region 18, and bottom Si-containing layer 10b. The thickness of the various layers may vary depending on the exact conditions employed in the formation of the BOX-adjusting oxide seed region as well as the second annealing step. Typically, however, the top Si-containing layer, at this point of the present invention, has a thickness of from about 10 to about 200 nm, with a thickness of from about 20 to about 150 nm being more highly preferred. The thickness of the Si can be further adjusted by growing an epi-Si layer over the pre-existing SOI layer.

Insofar as second buried oxide region 18 is concerned, the oxide region formed at this point of the present invention has a thickness of less than about 300, with a thickness of from about 100 to about 250 nm being more highly preferred, with the proviso that the second oxide region is thicker than the first oxide region. The thickness of the bottom Si-containing layer formed is inconsequential to the present invention.

In summary, the present invention provides a method of fabricating high-quality SOI substrate material that comprises a buried oxide layer that is continuous and has a thickness of about 300 nm or less. Moreover, the SOI substrate materials have high-quality electrical properties, as defined above, associated therewith. Additionally, the SOI substrate materials formed using the inventive method have a continuous and uniform BOX region that contains little or substantially no Si islands. The term “continuous” is used throughout the instant application as meaning a region that consisted of layer(s) which are not broken by regions of non-oxidized semiconductor material.

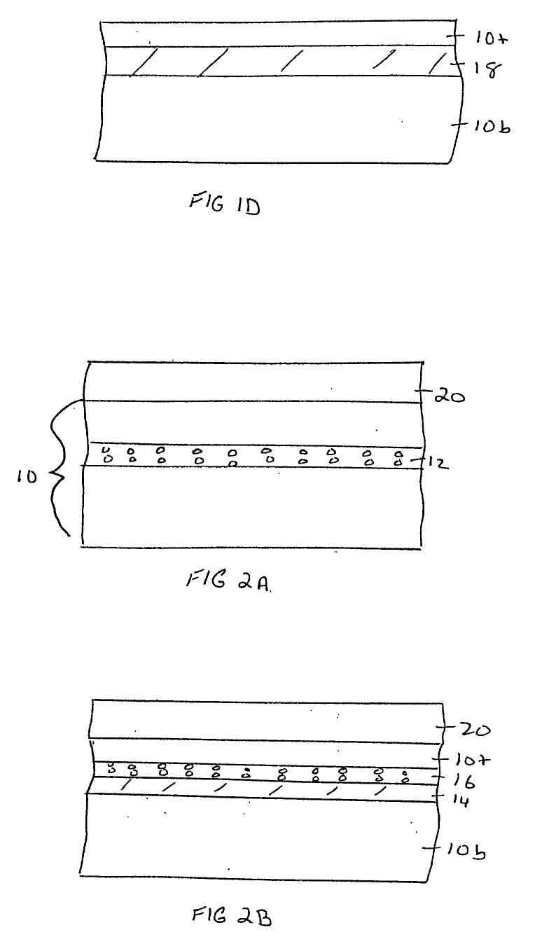

One optional, but highly preferred embodiment of the present invention is shown in FIGS. 2A-2B. In this optional embodiment, a Si layer, i.e., layer 20, is formed on the Si-containing substrate which includes at least primary oxide seed oxygen 12 (See FIG. 2A), and/or BOX-adjusting oxide seed region 16 (See FIG. 2B). In accordance with the present invention, the Si layer includes amorphous Si, polycrystalline Si (i.e., polySi), single crystal epitaxial Si (i.e., epi-Si) and combinations and multilayers thereof.

The Si layer is formed on the surface of the Si-containing substrate using conventional deposition processes well known to those skilled in the art. For example, Si layer 20 may be formed by chemical vapor deposition (CVD), plasma-enhanced chemical vapor deposition (PECVD), low-pressure chemical vapor deposition (LPCVD), sputtering, evaporation and chemical solution deposition. Alternatively, the Si layer may be formed by using a conventional epitaxial growth method.

The thickness of the Si layer formed on the Si-containing substrate may vary depending upon the required thickness necessary to achieve the formation of a BOX region having the above-mentioned properties. Typically, in the present invention, Si layer 20 has a thickness of from about 1 to about 10,000 Å, with a thickness of from about 500 to about 3000 Å being more preferred. Following formation of the Si layer on the surface of the Si-containing substrate, the structure is subjected to one of the above-mentioned annealing steps providing a structure which includes either the first or second oxide regions. The same silicon-containing deposition can be applied after the first implant step but before the BOX adjusting seed region to achieve a desirable final SOI thickness.

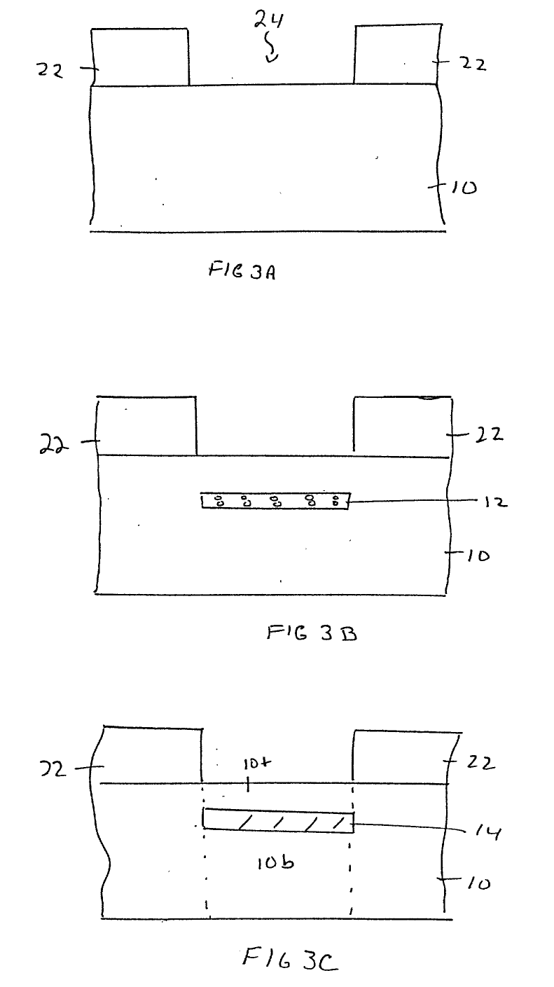

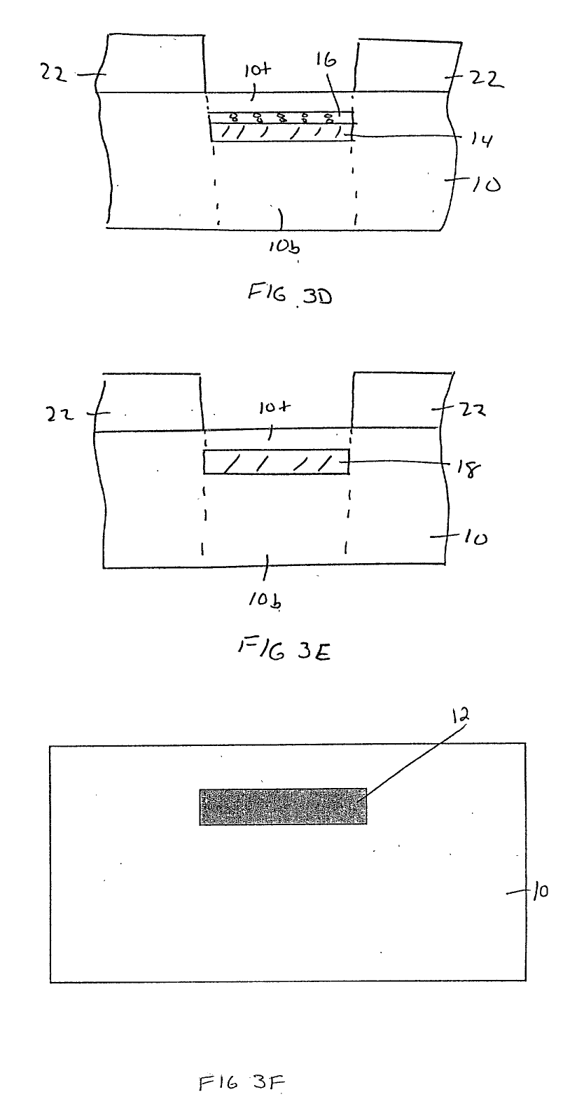

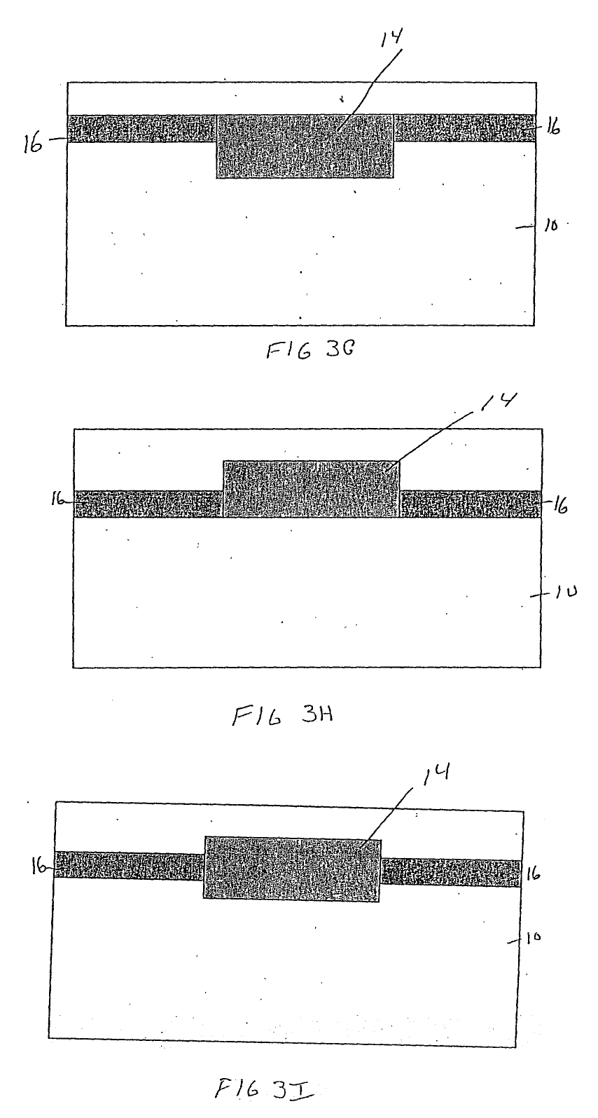

In addition to forming continuous BOX regions within the Si-containing substrate as shown, for example, in FIGS. 1A-1D, the present invention also works in cases wherein discrete and isolated BOX regions are formed within a surface of a Si-containing substrate. One embodiment of the discrete and isolation BOX-containing SOI substrate is shown, for example, in FIGS. 3A-3D.

The structure shown in FIG. 3A comprises a Si-containing substrate 10 having patterned mask 22 formed on a surface thereof. The patterned mask is composed of a dielectric material such as an oxide, nitride, oxynitride or multilayers thereof. The patterned mask is formed by depositing a layer of dielectric material on the surface of the Si-containing substrate by utilizing a conventional deposition process such as chemical vapor deposition (CVD), plasma-assisted CVD, sputtering, evaporation or chemical solution deposition. Alternatively, the dielectric material may be applied by a thermal oxidation, nitridation or oxynitridation process. After application of the dielectric material, conventional lithography and etching is employed in patterning the same. Note that the patterned mask contains at least one opening 24 that exposes a surface of the Si-containing substrate.

Next, and as shown in FIG. 3B, at least one discrete primary oxide seed region 12 is formed within substrate 10 by ion implanting through the at least one opening in the patterned mask using one of the above-mentioned oxygen ion implantation processes.

After the formation of primary oxide seed region 12, Si layer 20 (not shown) may optionally be formed on the exposed surfaces of the Si-containing substrate prior to the first annealing step. The dielectric mask may be removed prior to depositing or growing a Si layer 20. Note that although the Si layer is optional, it is preferred in some embodiments of the present invention.

The structure shown in FIG. 3B, which may include optional Si layer 20, is then subjected to the above-described first annealing step which results in the formation of the structure illustrated in FIG. 3C. Specifically, FIG. 3C comprises discrete first buried oxide region 14 which electrically isolates top Si-containing layer 10t from bottom Si-containing layer 10b. In some instances, the upper surface of layer 10t may be lower than the adjacent surface which contains the dieletric mask. Note that the dotted lines in the drawing represent the SOI region that is formed in the Si-containing substrate. In another embodiment, the dielectric mask is removed after the primary implant or implants but prior to the first anneal; See FIG. 3F.

Next, and as illustrated in FIG. 3D, BOX-adjusting seed region 16 is formed in substrate using the patterned mask as an implantation mask. Following formation of the BOX adjusting seed region, optional Si layer 20 (not shown) may be formed and thereafter the structure, with or without the optional Si layer, is subjected to the second annealing step providing the structure shown in FIG. 3E. Following the second annealing step, the patterned mask is removed from the structure using conventional stripping processes well known to those skilled in the art. The surface of layer 10t may be lower than the adjacent surface(s) which contains the dieletric mask.

In some embodiments of the present invention the patterned mask is removed prior to the first anneal, and in other embodiments patterned mask is removed after the first annealing step, but prior to formation of the BOX-adjusting seed region as shown in FIGS. 3F, 3G, 3H, and 3I, repectively.

It should be also noted that during the annealing steps of the present invention a surface oxide forms on the surface of the Si-containing substrate. The surface oxide is not shown in the drawings since it is typically removed after annealing using a chemical wet etch process that has a high selectivity for removing oxide as compared with Si.

The following examples are given to illustrate some of the advantages that can be achieved utilizing the inventive method.

### EXAMPLE 1

In this example, SOI substrates having a buried oxide thickness of about 187 nm were prepared in accordance with the method of the present invention. Specifically, the SOI substrates were prepared as follows: To various Si wafers, a first oxygen ion implant step using a first oxygen ion dose of about 4E17 cm⁻² at 185 keV and 570° C. was employed. Following the first oxygen ion implant step, a second oxygen ion implantation was carried out at room temperature and an ion dose of about 2E15 cm⁻².

In some embodiments (and for comparison purposes), this room temperature oxygen implant step was omitted). The Si wafers were then annealed at 1320° C. for 6 hours. Subsequently, a third oxygen implantation using an oxygen ion dose of about 5E17 cm⁻² was employed, and the samples were then annealed a second time at either 1320° C. for 6 hours or 1335° C. for 12 hours. This produced a BOX thickness of about 187 nm.

The electrical measurements of the BOX regions showed a breakdown field of about 7.2E6 volts/cm with high current leakage for the Si wafers that were not subjected to the room temperature oxygen ion implantation step; with the room temperature ion implant step, the breakdown voltage rose to 8.8E6 volts/cm. More importantly, however was that the wafers subjected to the inventive method showed a very small current leakage prior to breakdown.

### EXAMPLE 2

In this example, SOI substrates having a buried oxide thickness of about 160 nm were prepared in accordance with the method of the present invention. Specifically, the SOI substrates were prepared as follows: To various Si wafers, a first oxygen ion implant step using a first oxygen ion dose of about 2E17 cm⁻² at 185 keV and 570° C. was employed. Following the first oxygen ion implant step, a second oxygen ion implantation was carried out at room temperature and an ion dose of about 2E15 cm⁻².

The Si wafers were then annealed at 1320° C. for 6 hours. Subsequently, a third oxygen implantation using an oxygen ion dose of about 5E17 cm⁻² was employed, and the samples were then annealed a second time at either 1320° C. for 6 hours or 1335° C. for 12 hours. This produced a BOX thickness of about 160 nm.

The electrical measurements of the BOX showed a breakdown field of about of about 1.3-4.4E6 volts/cm with a high density of electrical “pinholes” (11 short circuits out of 50 devices measured) for the sample that was annealed with lower temperature and time. For higher annealing temperature and time, the breakdown field improved to 3.8-4.8E6 volts/cm with a very low density of pinholes (1 short circuit out of 50 devices measured).

While the present invention has been particularly shown and described with respect to preferred embodiments thereof, it will be understood by those skilled in the art that the foregoing and other changes in forms and details made be made without departing from the spirit and scope of the present invention. It is therefore intended that the present invention is not limited to the exact forms and details described and illustrated, but fall within the spirit and scope of the present invention.

Having thus described our invention in detail what we claim as new and desire to secure by the Letters Patent is:

1. A method of forming a silicon-on-insulator (SOI) substrate comprising the steps of:
forming a primary oxide seed region into a Si-containing substrate, said primary oxide seed region comprising at least damaged clusters intermixed with oxide precipitates;
subjecting said Si-containing substrate containing said primary oxide seed region to a first annealing step to convert the primary oxide seed region into a first buried oxide region;
forming a BOX-adjusting oxide seed region into said Si-containing substrate proximate to said first buried oxide region; and
subjecting said Si-containing substrate to a second annealing step to convert said BOX-adjusting oxide seed region and said first buried oxide region into a second buried oxide region, said second buried oxide region is thicker, and of improved quality, than the first buried oxide region.

2. The method of claim 1 wherein said primary oxide seed region is formed using at least one oxygen ion implantation process.

3. The method of claim 2 wherein said at least one oxygen ion implantation process comprises a base oxygen ion implantation process.

4. The method of claim 3 wherein said base oxygen ion implantation process is performed using an ion dose of from about 1E17 to about 8E17 cm⁻², an energy of from about 120 to about 400 keV and at a temperature of from about 200° to about 700° C.

5. The method of claim 3 further comprising a low-temperature, low-dose oxygen ion implantation process.

6. The method of claim 5 wherein said low-temperature, low-dose oxygen ion implantation process is performed using an ion dose of from about 1E13 to about 5E15 cm⁻², an energy of from about 120 to about 400 keV and at a temperature of from about 4K to about 150° C.

7. The method of claim 1 wherein said first annealing step is performed in an oxidizing ambient that is admixed with an inert gas or a chlorine-containing ambient.

8. The method of claim 7 wherein said oxidizing ambient comprises at least one oxygen-containing gas selected from the group consisting of O₂, NO, N₂O, air, ozone and mixtures thereof.

9. The method of claim 1 wherein said first annealing step comprises an admixture comprising from about 0.1 to about 100% oxidizing ambient and from about 99.9 to about 0% inert gas.

10. The method of claim 1 wherein said BOX-adjusting seed region is formed using at least one oxygen ion implantation process.

11. The method of claim 10 wherein said at least one oxygen ion implantation process comprises a base oxygen ion implantation process.

12. The method of claim 11 wherein said base oxygen ion implantation process is performed using an ion dose of from about 1E17 to about 8E17 cm⁻², an energy of from about 120 to about 400 keV and at a temperature of from about 200° to about 700° C.

13. The method of claim 11 further comprising a low-temperature, low-dose oxygen ion implantation process.

14. The method of claim 13 wherein said low-temperature, low-dose oxygen ion implantation process is performed using an ion dose of from about 1E13 to about 5E15 cm⁻², an energy of from about 120 to about 400 keV and at a temperature of from about 4K to about 150° C.

15. The method of claim 1 wherein said second annealing step is performed in an oxidizing ambient that is admixed with an inert gas or a chlorine-containing ambient.

16. The method of claim 15 wherein said oxidizing ambient comprises at least one oxygen-containing gas selected from the group consisting of O₂, NO, N₂O, air, ozone and mixtures thereof.

17. The method of claim 1 wherein said second annealing step comprises an admixture comprising from about 0.1 to about 100% oxidizing ambient and from about 99.9 to about 0% inert gas.

18. The method of claim 1 further comprising forming a patterned mask on said Si-containing substrate prior to, or after forming said primary oxide seed region.

19. A method of forming a high-quality silicon-on-insulator (SOI) substrate comprising the steps of:
performing a first oxygen ion implant into a Si-containing substrate, said first oxygen ion implant is carried out at an ion dose of from about 1E17 to about 8E17 cm⁻² and at a temperature of from about 200° to about 700° C.;
performing a second oxygen ion implant on said Si-containing substrate, said second ion implant is carried out at an ion dose of from about 1E13 to about 5E15 cm⁻² and at, temperature of from about 4K to about 150° C.;
subjecting said Si-containing substrate to a first annealing step;
performing a third oxygen ion implant, said third oxygen ion implant is carried out at an ion dose of from about 1E17 to about 8E17 cm⁻² and at a temperature of from about 200° to about 700° C.; and
subjecting said Si-containing substrate to a second annealing step.

20. The method of claim 19 wherein the combined oxygen implants have a total oxygen dosage that is between 5E17 to 1.2E18 cm⁻².
